(19) United States
(12) Patent Application Publication
(10) Pub. No.: US 2008/0048582 A1
(43) Pub. Date: Feb. 28, 2008

(54) PWM METHOD AND APPARATUS, AND LIGHT SOURCE DRIVEN THEREBY

(76) Inventor: Shane P. Robinson, Gibsons (CA)

Correspondence Address: PATTERSON & SHERIDAN, L.L.P., 3040 POST OAK BOULEVARD, SUITE 1500, HOUSTON, TX, 77056, US

(21) Appl. No.: 11/844,770

(22) Filed: Aug. 24, 2007

Related U.S. Application Data
(60) Provisional application No. 60/823,732, filed on Aug. 28, 2006.

(51) Int. Cl. H05B 37/02; H03K 7/08

(52) U.S. Cl. 315/291; 332/109

(57) ABSTRACT

The present invention provides a pulse-width modulation (PWM) method and apparatus, and light source driven thereby. In particular, the present invention provides a PWM method and apparatus for generating a PWM signal having a desired resolution and frequency using generating means traditionally limited to providing PWM signals having a lower resolution and/or frequency. The PWM method and apparatus of the present invention may be used in a number of applications where a relatively high PWM resolution and/or frequency is desired, but where selection of generating means for generating such PWM signals is relatively limited by cost and/or other such constraints. For example, a PWM signal generated by the method and apparatus of the present invention may be useful in accurately controlling the output of the one or more light-emitting elements of a light source, namely to control a dimming and/or colour level thereof, without using driving components that may be relatively costly for the application at hand.

### CROSS-REFERENCE TO RELATED APPLICATIONS

This application claims benefit of United States provisional patent application Ser. No. 60/823,732, filed Aug. 28, 2006, which is herein incorporated by reference.

### BACKGROUND OF THE INVENTION

1. Field of the Invention

The present invention pertains to the fields of lighting and signal modulation and, in particular, to a pulse-width modulation (PWM) method and apparatus, and light source driven thereby.

2. Description of the Related Art

Advances in the development and improvements of the luminous flux of light-emitting devices such as solid-state semiconductor and organic light-emitting diodes (LEDs) have made these devices suitable for use in general illumination applications, including architectural, entertainment, and roadway lighting. Light-emitting diodes are becoming increasingly competitive with light sources such as incandescent, fluorescent, and high-intensity discharge lamps. Also, with the increasing selection of LED wavelengths to choose from, white light and colour changing LED light sources are becoming more popular. As such, there is an ever present need for improved control over the light output from such light sources.

An advantage of LEDs is that their turn-ON and turn-OFF times are typically less than 100 nanoseconds. The average luminous intensity of an LED can therefore be controlled using a fixed constant-current power supply together with pulse width modulation (PWM) of the LED drive current, wherein the time-averaged luminous intensity is linearly proportional to the PWM duty cycle. This technique is disclosed in U.S. Pat. No. 4,090,189 and documented in Gage, S., M. Modapp, D. Evans, and H. Sorenson. 1977, Optoelectronics Applications Manual, New York, N.Y.: McGraw-Hill Book Company, wherein a single LED colour was considered. As is also known, pulse code modulation (PCM) is yet another way to control the operation of LEDs.

According to W. Howell in a web document “A Brief History of LED Lighting”, Middlesex, UK: Artistic License Inc., 2002, J. Laidman developed a commercial product for a company called Sound Chamber that employed a PWM-based controller for a multiplicity of single-colour LEDs in 1979. A similar PWM-based control method and apparatus also employing a multiplicity of single-colour LEDs was later disclosed in U.S. Pat. No. 4,845,481. According to these inventions, an essentially infinite range of colours can be produced by optically blending single colours of different luminous intensities.

Though practical, such modulated signals generally have to meet a number of requirements in order to create apparent lighting effects that will be pleasantly perceived by humans. Namely, modulation at higher frequencies may be required to avoid certain frequency-dependent effects, such as light source flickering, thermal cycling and audible noise.

Also, in many applications, precise control of the LED output may be required, for instance to provide desired light source dimming and/or colour control. The high resolution PWM signals required to provide such control, particularly at switching frequencies selected to minimise the above and other such undesirable frequency-dependent effects, generally require the use of high speed microprocessors, which can be prohibitively expensive and can be impractical for most lighting applications.

The following provide some examples of apparatus and/or methods for generating PWM signals.

In United States Patent Application No. 2005/0191043, a motor driving apparatus is disclosed, wherein a power circuit varies an output voltage by changing a value of a feedback resistance at a time of at least one of activation and termination of a motor, thereby enabling to activate the motor at any one of a high speed and a low speed. In the disclosed apparatus, a PWM signal, generated by comparing an input signal with a reference saw-tooth signal, is used to drive a metal oxide semiconductor (MOS) of the apparatus.

In United States Patent Application No. 2005/0190142, a method and apparatus are disclosed to control the brightness of a display while accounting for ambient light corrections, wherein an ambient light sensor produces a current signal that varies linearly with the level of ambient light. This current signal is multiplied by a user dimming control input to generate a brightness control signal that automatically compensates for ambient light variations. The multiplying function provides noticeable user dimming control at relatively high ambient light levels. The dimming control input may comprise a PWM logic signal, or a DC signal. In the latter case, the DC signal and a reference saw-tooth ramp signal are provided as input to a comparator, which generates an equivalent PWM logic signal.

In the EDN Design Idea titled “DDS circuit generates precise PWM waveforms”, published Oct. 2, 2003 (http://www.edn.com/article/CA324406.html), a circuit is described for generating a precise PWM signal, wherein a high-accuracy saw-tooth waveform with fine frequency resolution is provided by a direct digital synthesiser (DDS) as input to a comparator, whose threshold level is controlled by an actuator feedback loop.

The above examples provide various means for generating a PWM signal. None of the above references, however, disclose adequate means for generating PWM signals suitable, for example, in providing a high degree of LED light source output control while respecting manufacturing and cost limitations associated with such light sources.

Consequently, there is a need for a method and apparatus for generating PWM signals that overcome some of the drawbacks of known PWM techniques.

This background information is provided to reveal information believed by the applicant to be of possible relevance to the present invention. No admission is necessarily intended, nor should be construed, that any of the preceding information constitutes prior art against the present invention.

### SUMMARY OF THE INVENTION

An object of the present invention is to provide a PWM method and apparatus.

Another object of the present invention is to provide a light source driven by the above PWM method and apparatus.

In accordance with an aspect of the present invention, there is provided an apparatus for generating a PWM signal having a desired resolution and frequency, the apparatus comprising: a generating module for generating a first PWM signal having the desired resolution; and a comparing module adapted to compare said first PWM signal to a reference signal indicative of the desired frequency and thereby generate a second PWM signal substantially having the desired resolution and frequency.

In accordance with another aspect of the present invention, there is provided a method of generating a PWM signal having a desired frequency and resolution, the method comprising the steps of: generating a first PWM signal having the desired resolution; and comparing said first PWM signal to a reference signal indicative of the desired frequency to generate a second PWM signal substantially having the desired frequency and resolution.

In accordance with another aspect of the present invention, there is provided a light source comprising: one or more light-emitting elements; and a driving system for driving each one of said one or more light-emitting elements at a given frequency and at a respective relative intensity, said driving system comprising: a generating module for generating, for each of said one or more light-emitting elements, a first PWM signal having a duty-cycle indicative of said respective relative intensity; and a comparing module adapted to compare each said first PWM signal to a reference signal indicative of said given frequency and thereby generate a respective second PWM signal at said given frequency conducive to driving a respective one of said one or more light-emitting elements at said respective relative intensity.

### BRIEF DESCRIPTION OF THE FIGURES

FIG. 1 is a high level box diagram of an apparatus for generating a PWM signal, in accordance with an embodiment of the present invention;

FIG. 2 is a diagram of an apparatus for generating a PWM signal, in accordance with an embodiment of the present invention;

FIG. 3 is a diagram of a light source driven by a PWM signal, in accordance with an embodiment of the present invention; and

FIG. 4 is a diagram of another light source driven by PWM signals, in accordance with an embodiment of the present invention.

### DETAILED DESCRIPTION OF THE INVENTION

### Definitions

The term “light-emitting element” is used to define a device that emits radiation in a region or combination of regions of the electromagnetic spectrum for example, the visible region, infrared and/or ultraviolet region, when activated by applying a potential difference across it or passing a current through it, for example. Therefore a light-emitting element can have monochromatic, quasi-monochromatic, polychromatic or broadband spectral emission characteristics. Examples of light-emitting elements include semiconductor, organic, or polymer/polymeric light-emitting diodes, optically pumped phosphor coated light-emitting diodes, optically pumped nano-crystal light-emitting diodes or other similar devices as would be readily understood by a worker skilled in the art. Furthermore, the term light-emitting element is used to define the specific device that emits the radiation, for example a LED die, and can equally be used to define a combination of the specific device that emits the radiation together with a housing or package within which the specific device or devices are placed.

As used herein, the term “about” refers to a ±10% variation from the nominal value. It is to be understood that such a variation is always included in any given value provided herein, whether or not it is specifically referred to.

Unless defined otherwise, all technical and scientific terms used herein have the same meaning as commonly understood by one of ordinary skill in the art to which this invention belongs.

The present invention provides a pulse-width modulation (PWM) method and apparatus, and light source driven thereby. In particular, the present invention provides a PWM method and apparatus for generating a PWM signal having a desired resolution and frequency using generating means traditionally limited to providing PWM signals having a resolution and/or frequency lower than that desired.

The apparatus comprises a generating module which is configured to generate as an output a first PWM signal having a desired resolution at a first frequency less than the desired frequency. This first PWM signal, or an intermediate signal indicative of the duty-cycle thereof, is provided to a first input of a comparing module. A reference signal indicative of the desired frequency is also provided to a second input of the comparing module. The comparing module is configured to generate a second PWM signal which has substantially the desired frequency and resolution, based on a comparison of the first PWM signal and the reference signal. In this manner the apparatus and method according to the present invention can generate a PWM control signal having a desired resolution and frequency, which is not dictated by the operation speed of the generating module.

In one embodiment, the apparatus further comprises a converting module which is configured to convert the first PWM signal into an intermediate signal which is provided to the first input of the comparing module. As above, the comparing module is configured to generate a second PWM signal which has substantially the desired frequency and resolution, based on a comparison of the intermediate signal and the reference signal. For example, the converting module may convert the first PWM signal into an analog signal indicative of the first PWM signal duty cycle.

In another embodiment, the apparatus is realised in the digital domain, wherein the first PWM signal is provided as an input to a phase lock loop (PLL), for example, used to up -convert the frequency of the first PWM signal while substantially maintaining the duty cycle thereof. In such an embodiment, the output of the PLL can be used, for example, as the reference signal, generally subsequent to frequency division, such that the output signal is generated a desired frequency expressed as a multiple of the first PWM signal frequency.

It will be appreciated that different combinations and configurations of the above modules may be provided by distinct and/or combined modules operatively coupled to produce the desired result. For example, each of the above modules can, in one embodiment, be integrated within a single circuit or chip design to provide a desired output, whereas in another embodiment, each of the above modules are assembled as separate components of a combined circuit. In another embodiment, the converting module, comparing module, and reference signal generator are all contained within a single chip or device and operatively coupled to the generating module, such as a processor or the like. Other combinations and configurations will become apparent to the person of skill in the art upon reference to the following description.

The PWM method and apparatus of the present invention may be used in a number of applications where a relatively high PWM resolution and/or frequency is desired, but where selection of generating modules for generating such PWM signals is relatively limited by cost and/or other such constraints. For example, a PWM signal generated by the method and apparatus of the present invention may be useful in accurately controlling the output of the one or more light-emitting elements of a light source, namely to control a dimming and/or colour level thereof, without using driving components that may be relatively costly for the application at hand.

Though the following discussing focuses mainly on applying the PWM method and apparatus of the present invention in the context of providing a driving system for driving the one or more light-emitting elements of a light source, the person of skill in the art will readily understand the applicability of the disclosed PWM method and apparatus to a number of other applications, for example motor control or brake control and the like.

In general, control of the light output from a light-emitting element may be obtained using a pulse width modulation (PWM) or pulse code modulation (PCM) signal, as discussed above. Using these modulation methods, the light-emitting element will be successively driven to switch between states of substantially no light emission and substantially full light emission. If the switching frequency is sufficiently high, a substantially continuous output intensity, which is substantially equal to the time averaged light output by the light-emitting element, will be perceived by a human observer.

As such, PWM may be used to modulate the output of a light-emitting element to provide a desired output intensity. By adjusting the duty cycle of the PWM signal used to drive the light-emitting element, namely by varying the width of the pulses thereof, the output intensity may also be adjusted. Such intensity control may be implemented to provide, for example, various light source dimming levels.

In a white light or colour changing light source, the outputs of two, three or more light-emitting elements, each having a respective emission spectrum (e.g. peak wavelength(s), predominant colour, etc.), may be combined to produce a desired output spectrum (e.g. colour, spectral profile, colour quality and/or rendering efficiency, chromaticity, etc.). By adjusting the respective intensities of the light-emitting elements, thereby varying the combined output spectrum of the light source, various colour outputs, which may include white light, may be generated. Overall adjustment of the respective light-emitting element intensities, while maintaining substantially constant intensity ratios, may also be implemented to provide various light source dimming levels while substantially maintaining an output spectrum or colour. Alternatively, through the variation of the intensity ratios of the different colour light-emitting elements, different light colours and/or characteristics thereof can be created.

Consequently, to provide adequate light source dimming control and/or output colour control, the respective PWM signals driving the one or more light-emitting elements of a light source should be of sufficiently high resolution. For example, for colour control in a red-green-blue (RGB) light source, a high resolution dimming method may be required. Namely, at full light levels, an 8-bit resolution may be required for each colour of an RGB light source to maintain the output colour to within 1 or 2 just-noticeable differences. Furthermore, in order to provide a dimming range useful for most lighting markets, a 1:100 dimming range may be desired, bringing the total required resolution for each colour to about 14 to 15 bits, for example.

In addition, while PWM may be a suitable technique for light source dimming and colour control, a PWM drive signal should also meet, in one embodiment, a number of requirements in order to create apparent lighting effects that will be pleasantly perceived by humans. For example, the PWM frequency could be selected to exceed about 100 Hz in order to avoid perceptible flickering of the light produced. In addition, because the components of light-emitting elements can transport and store heat at different rates, higher PWM frequencies can reduce the effects of stress caused by thermal cycling of the light-emitting element; in typical light-emitting element packages, detrimental effects of temperature fluctuations can become negligible for PWM frequencies beyond about 1 kHz, for example. Furthermore, switching between about 20 Hz and about 20 kHz can cause audible noise such that switching at a speed greater then about 20 kHz may be desired. Currently, standard mainstream low-cost microcontrollers can offer resolution up to 16 bits, however this resolution is created at a relatively low frequency. Alternatively, these microcontrollers can offer a high frequency option within the kHz range, however, at a lower resolution level.

A person of skill in the art will understand that the above characteristics and constraints may also be applicable to various types of light sources, whether they comprise a single light-emitting element, three light-emitting elements as in a RBG light source, four light-emitting elements as in a red (R), amber (A), green (G) and blue (B) light source (RAGB), or a group, array or combination thereof, without departing from the general scope and nature of the present disclosure.

In general, the speed of a PWM channel, for example generated using a microcontroller or the like, can be expressed as follows: Processor Speed=(2^{PWM bit resolution})×(PWM frequency). As such, if a certain resolution is required, the traditional solution for increasing the PWM frequency is to increase the processor speed. This may however not be an option, particularly when faster processors become prohibitively costly for the application at hand.

The method and apparatus of the present invention provide an alternative to increasing processor speed in order to meet resolution requirements.

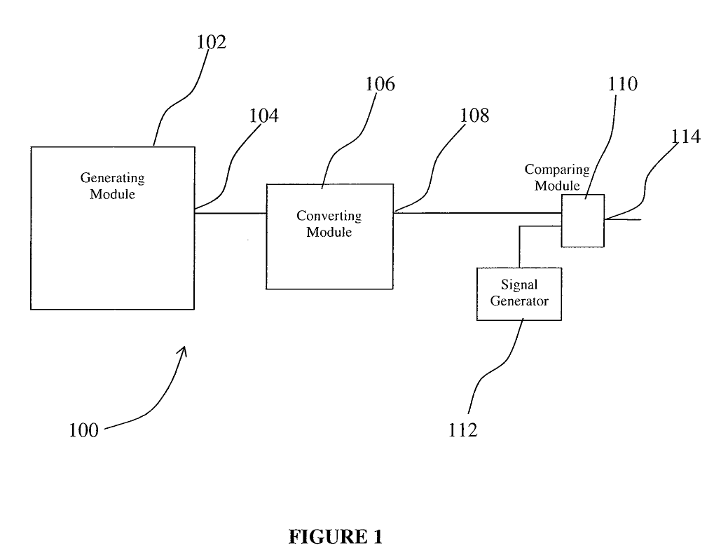

The apparatus of the present invention, schematically illustrated as apparatus 100 in FIG. 1 and illustratively applicable in providing a driving system for driving the light-emitting elements of a light source, generally comprises a generating module 102 for generating at output 104 a first PWM signal having a desired resolution at a first frequency; a converting module 106 for converting this first PWM signal into an intermediate signal (e.g. an analog signal indicative of the first PWM signal duty cycle) provided at output 108, and comparing module 110 adapted to compare the intermediate signal to a reference signal indicative of a desired frequency (e.g. reference signal generated at the desired frequency) and thereby generate a second PWM signal having the desired frequency and resolution at output 114. The reference signal can be generated by a signal generator 112, for example.

It will be appreciated, as described above, that other embodiments may be considered herein in which the converting module 106 is omitted. For example, when implemented in the digital domain, the first PWM signal may be used as input to a phase-lock loop (PLL), for example, and compared to a reference signal indicative of the desired frequency (e.g. frequency-divided output of PLL).

### Generating Module

To generate a first PWM signal, various generating modules may be considered. In one embodiment, the generating module is a microprocessor (or controller) configured to generate a PWM signal at the desired resolution, but at a frequency other than that desired. For instance, the output frequency of the microprocessor may be lower than the desired frequency, thereby allowing to maximise a resolution of the first PWM signal while remaining within the processing limits of the microprocessor, generally set by the microprocessor's clock speed.

For example, in one embodiment, the microprocessor is a 60 MHz processor configured to generate a 14 bit PWM signal at about 3.66 kHz. As described above, though a 14 bits PWM signal may have a sufficiently high resolution to adequately control, for example, the colour and dimming level of a given light source, driving the light-emitting elements of the given light source at 3.66 kHz may generate some undesirable effects, such as audible noise. Using the method and apparatus of the present invention, however, this frequency may be increased to a more favourable drive frequency while substantially maintaining the desired resolution of about 14 bits.

Clearly, the same processor may be used to generate a lower or higher resolution PWM signal while respectively increasing or decreasing the output frequency thereof. For example, if a 16 bit PWM signal is required from a 60 MHz processor, the output frequency may be set to about 900 Hz. A drive frequency of 900 Hz will likely generate various undesirable frequency-dependent effects. The apparatus and method of the present invention can enable this PWM frequency to be increased without increasing the processor speed and without substantially reducing the resolution of the resulting PWM signal.

A person of skill in the art will understand that other generating modules may be considered without departing from the general scope and nature of the present disclosure. For instance, faster or slower processors may be used to provide first PWM signals of an initial resolution and frequency. In general, the selection of the processor can depend on the application at hand and the cost of the processor deemed reasonable for the particular application.

In another embodiment of the present invention, the generating module for generating the first PWM signal can be configured as a digital signal processor, a field programmable gate array, one or more counters, one or more timers (such as, for example, a 555 timer or the like), operational amplifier circuits or other means as would be readily understood by a worker skilled in the art.

In another embodiment of the present invention, the generating module is a processor and the first PWM signal is generated in a digital format such as I²C or SPI from the processor.

### Converting Module

In one embodiment, the first PWM signal is provided to a converting module for conversion into an intermediate signal. In general, the intermediate signal will be indicative of the duty-cycle of the first PWM signal such that information modulated in the latter is substantially maintained in the former. For example, in one embodiment, the converting module is configured such that a resolution of the first PWM signal is substantially maintained when generating the intermediate signal.

In one embodiment, the converting module comprises a filter, digital to analog converter (DAC) and/or the like to convert the first PWM signal into an analog signal indicative of the duty cycle of the first PWM. For instance, a low pass filter may be used to provide this effect. For example, a passive first order low pass filter may be used, the filter optionally comprising a single resistor-capacitor (RC) circuit adapted to filter the first PWM signal output from the generating module. In another example, an active and/or higher order low pass filter may be used to provide lower ripple on the output with a faster response to sudden duty cycle changes in the first PWM signal. Such an alternative would generally incur additional costs, but could be considered in certain applications where the benefits associated with these higher efficiency filters outweigh the additional costs.

In one embodiment, the cut-off frequency of the low pass filter can be set to minimise output ripple but maximise speed. For example, in an embodiment where the frequency of the first PWM signal is of about 3.66 kHz, a cut-off frequency of 1 kHz may be used to provide sufficient filtering while still allowing for rapid changes in the duty-cycle of the first PWM signal. It will be understood that the cut-off frequency of such low pass filters may be adjusted as a function of the frequency of the first PWM signal and as a function of specific signal quality characteristics dictated by the application for which the apparatus is to be used.

A person of skill in the art will understand that other converting modules, which may include, but are not limited to, various combinations and/or types of DACs, filters such as low pass filters, band pass filters, notch filters, etc. and the like, may be considered without departing from the general scope and nature of the present disclosure.

In another embodiment of the present invention, the converting module can be formed as part of the processor that is used to generate the first PWM signal. For example, a digital to analog converter can be present within the processor, wherein the first PWM signal is directly converted into an analog signal.

### Comparing Module

The intermediate signal provided by the converting module (e.g. an analog signal), or the first PWM signal itself when a comparing module is omitted (e.g. when operating in the digital domain with a phase-lock loop) is generally used as input to a comparing module. This comparing module may be configured to compare the first or intermediate signal to a reference signal indicative of a desired frequency, (e.g. generated at or as a known function of the desired frequency), and thereby generate a second PWM signal at about the desired frequency. In general, the resolution with which the PWM signal is generated will be substantially maintained through the optional conversion and comparing processes such that the second PWM signal will have a substantially same resolution as the first PWM signal.

For example, in one embodiment, an analog intermediate signal may be compared to a reference waveform having the desired frequency such that a duty-cycle of the second PWM signal is dictated by the successive intersections of the analog signal with this reference signal. It will be appreciated that the compared signals may be modified (e.g., DC offset, normalisation, scaling, phase-shift, modulation, etc.) before such comparison is performed to provide a desired effect (e.g., linear and/or non-linear duty-cycle transformation, scaling, phase shift, modulation, etc.).

In one embodiment, the reference waveform comprises a saw-tooth or triangle waveform thereby generally providing a linear transformation of the analog signal into the second PWM signal. For example, in an embodiment where the analog signal is represented by a slowly varying signal (e.g., a DC signal) whose value is indicative of the duty-cycle of the first PWM signal, by comparing the normalised analog signal with an equally normalised triangle or saw-tooth waveform and by switching an output of the comparing module between high and low values at each intersection between these two signals, the PWM signal output from the comparing module will generally have a substantially same duty-cycle as that of the first PWM signal, but will be modulated at the frequency of the reference waveform. In this example, when a value of the analog signal varies by a factor of two (2), for example, so will the duty-cycle of the second PWM signal. Furthermore, if the analog signal is generated such that a value thereof is defined with a substantially same resolution as the duty-cycle of the first PWM signal, then this resolution can be substantially maintained in the second PWM signal.

In another embodiment, the relative amplitudes of the analog signal and the reference signal may be adjusted such that the duty-cycle of the second PWM signal is scaled relative to the first duty-cycle, thereby generating a second PWM signal whose duty-cycle is defined by a linear function of the first duty-cycle.

In another embodiment, the reference signal is a non-linear signal, such as a sinusoid or the like, such that the second duty-cycle is defined by a non-linear function of the first duty-cycle, while substantially maintaining a resolution of the first PWM signal.

Other such functional variations of the second duty-cycle relative to the first, whether performed directly by proper selection of the reference waveform or indirectly by pre-processing the analog and/or reference waveform, should be apparent to a person of skill in the art and are thus not meant to depart from the general scope and nature of the present disclosure.

In one embodiment, the comparing module comprises a high speed comparator that continually compares the analog signal, for example on the positive input of the comparator, to a reference waveform, in this example on the negative input of the comparator.

In another embodiment, the comparing module comprises a phase-locked loop where the first PWM signal is provided directly to an input thereof and where the reference signal is provided as a function of the phase-lock loop output signal.

In one embodiment, the frequency of the reference waveform is set above about 20 kHz such that an output thereof may be used to drive a light-emitting element while minimising undesirable frequency-dependent effects such as flickering, thermal cycling and/or audible noise. For example, the frequency of the reference waveform may be set at about 30 kHz.

In another embodiment, the apparatus of the present invention uses two or more channels to generate corresponding PWM signals, for example, in order to drive two or more respective light-emitting elements in a given light source. In general, the PWM registers of common processors are all based on a common clock. As such, at the start of a new PWM cycle, all of the outputs are asserted at the same time causing a large current draw from the power supply. To alleviate the load on the power supply, in one embodiment, the reference waveform used by the comparing module for a given channel may be phase shifted compared to the others. By phase shifting each reference waveform, the original synchronised PWM signals can be spread over a period of time, thereby reducing a sudden load on the power supply. For example, in one embodiment where three such channels are used, namely to drive the light-emitting elements of a RGB light source, each channel can be phase shifted by ⅓ of a PWM period. The power supply will then see about ⅓ the current rise at a given time.

In another embodiment, data can be embedded in the second PWM signal by modulating the reference waveform. A light source, driven as such, could act as a data source or data transmitter. In one example, an amplitude-modulated, a frequency-modulated or phase-modulated data signal is superimposed on the reference signal to modulate the second PWM signal.

In another embodiment, a substantially continuous signal can be achieved by using more than one light-emitting element and phase shifting the reference signals that control individual light-emitting elements or groups of light-emitting elements such that one or more light-emitting elements are always energised, for example when the sum of their duty cycles equals or exceeds the reference signal period.

In one embodiment, a continuous signal can be amplitude-modulated, frequency-modulated, or phase-modulated with a plurality of frequencies or mutually orthogonal digital codes, as would be readily understood by a worker skilled in the art. Each of these frequencies can be further modulated using one of many known modulation methods, including amplitude modulation (AM), frequency modulation (FM), frequency shift key (FSK) modulation, pulse code modulation (PCM), pulse point modulation (PPM), phase shift key (PSK) modulation, amplitude shift keying (ASK), amplitude phase keying (APK), quadrature amplitude modulation (QAM), discrete multitone modulation (DMM), code division multiple access (CDMA), and differential chaos shift keying (DCSK) methods, or any other method as would be readily understood, and wherein each frequency or mutually orthogonal code represents an independent data communication channel.

In another embodiment of the present invention, the comparing module can be an operational amplifier, Schmitt trigger or other means as would be readily understood by a worker skilled in the art.

The invention will now be described with reference to specific examples. It will be understood that the following examples are intended to describe embodiments of the invention and are not intended to limit the invention in any way.

### EXAMPLES

### Example 1

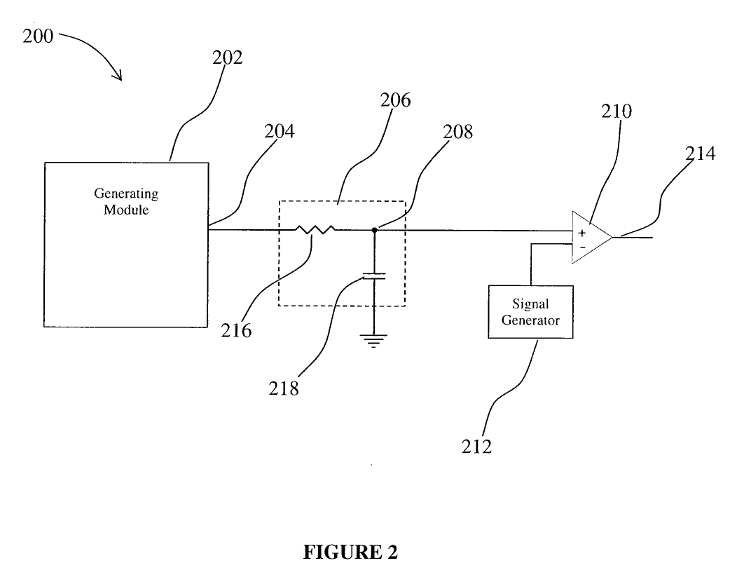

With reference to FIG. 2, an apparatus for generating a PWM signal, generally referred to using the numeral 200, and in accordance with one embodiment of the present invention, will now be described. The apparatus 200 generally comprises a generating module 202 for generating at output 204 a first PWM signal having a desired resolution and a first frequency. The first PWM signal is then converted by a converting module 206 to generate an analog signal at node 208 indicative of the duty-cycle of the first PWM signal. The analog signal is then provided as input to a comparing module 210, such as a high speed comparator or the like, adapted to compare the analog signal to a reference signal having a desired frequency (illustratively provided by signal generator 212), and thereby generate a second PWM signal substantially having the desired frequency and resolution at output 214.

The generating module 202 may comprise a microprocessor or the like, adapted to generate the first PWM signal at the desired resolution but limited to generating this signal at a frequency lower than the desired frequency. For example, in one embodiment, the generating module 202 comprises a 60 MHz processor configured to generate a 14 bit PWM signal at about 3.66 kHz.

The converting module 206 generally comprises a passive low pass filter comprising a resistor 216 and capacitor 218. In general, the cut-off frequency of the low pass filter can be set to minimise output ripple but maximise speed. In the above example wherein a first PWM signal is generated at 3.66 kHz, a cut-off frequency of about 1 kHz may be used to provide adequate results. In general, the filter components can be selected to provide sufficient filtering while allowing for rapid changes in the duty-cycle of the first PWM signal. A person of skill in the art will readily understand that various resistor and capacitor combinations may be considered depending on the output characteristics of the converting module desired or required for a given application, and consequently, such combinations should not be considered to depart from the general scope and nature of the present disclosure. Furthermore, it will be appreciated that other types of passive and/or active filters, including first or higher order filters, may also be considered in the present context.

The comparing module 210 generally comprises a high speed comparator that continually compares the analog signal at node 208 to a reference waveform (e.g., a triangle or saw-tooth waveform or the like) provided on the negative input of the comparator 210 from a waveform generator 212 or the like. The frequency of the reference waveform can be set at the desired frequency, for example 30 kHz, such that the PWM signal generated at the output 214 of the comparator 210 will generally comprise a reproduced PWM signal having the desired resolution with the desired frequency (e.g., the original resolution of about 14 bit but a frequency of about 30 kHz instead of 3.66 kHz).

### Example 2

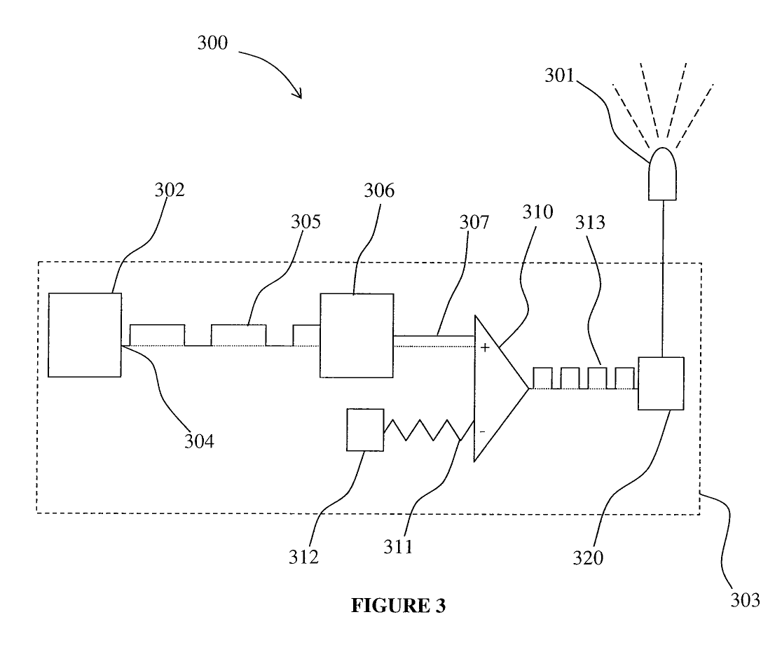

With reference now to FIG. 3, a light source driven by a PWM signal, generally referred to using the numeral 300, and in accordance with one embodiment of the present invention, will now be described. The light source 300 generally comprises a light-emitting element 301 and a driving system 303 therefor.

In general, the driving system 303 comprises a generating module 302 for generating at output 304 a first PWM signal 305 having a desired resolution and a first frequency. The first PWM signal is then converted by a converting module 306 to generate an analog signal 307 indicative of the duty-cycle of the first PWM signal 305. The analog signal 307 is then provided as input to a comparing module 310, such as a high speed comparator or the like, adapted to compare the analog signal 307 to a reference waveform, as in triangle or saw tooth signal 311, having a desired frequency (illustratively provided by signal generator 312). By comparing the analog signal 307 with the reference waveform 311, a second PWM signal 313, is generated having the desired frequency and resolution. This second PWM signal 313 can then be used in driving the light-emitting element 301 via driver 320.

The generating module 302 may comprise a microprocessor or the like, adapted to generate the first PWM signal 305 at the desired resolution but limited to generating this signal at a frequency lower than a desired frequency. For example, in one embodiment, the generating module 302 comprises a 60 MHz processor configured to generate a 14 bit PWM signal at about 3.66 kHz.

The converting module 306 generally comprises various types of filters and/or DACs suitable in providing an analog signal 307 of suitable characteristics for the application at hand. For example, a passive low pass filter comprising a single RC circuit may be used in some applications, whereas active and/or higher order filters may used in other applications where a higher quality output is desired or required. In general, converting module can be selected to minimise output ripple but maximise speed. In the above example wherein a first PWM signal 305 is generated at 3.66 kHz, a passive low pass filter may be provided with a cut-off frequency of about 1 kHz to provide adequate results. In general, the converting module can be selected to provide an effective conversion (e.g., sufficient filtering) while allowing for rapid changes in the duty-cycle of the first PWM signal 305.

The comparing module 310 generally comprises a high speed comparator that continually compares the analog signal 307 to a saw-tooth or triangle waveform 311 provided on the negative input of the comparator 310 from a waveform generator 312 or the like. The frequency of the saw-tooth waveform 311 can be set at the desired frequency, for example 30 kHz, such that the PWM signal 313 output from the comparator 310 will generally comprise a reproduced PWM signal having the desired resolution but the higher frequency (e.g., the original resolution of about 14 bits but a frequency of about 30 kHz instead of 3.66 kHz).

In one embodiment, data could also be embedded in the second PWM signal 313 by frequency modulating the reference waveform 311. If the light source 300 is driven as such, it could act as a data source or data transmitter. The reference waveform 311 could also be modulated in other ways to transmit data, as one who is skilled in the art will readily understand.

While the analog signal 307 is illustrated herein as a straight line generally indicative of a substantially constant first PWM signal duty-cycle, a person of skill in the art will understand that variations in the first PWM signal duty-cycle will generally be reflected in the analog signal 307 such that these variations may be substantially transferred to the duty cycle of the second PWM signal 313.

### Example 3

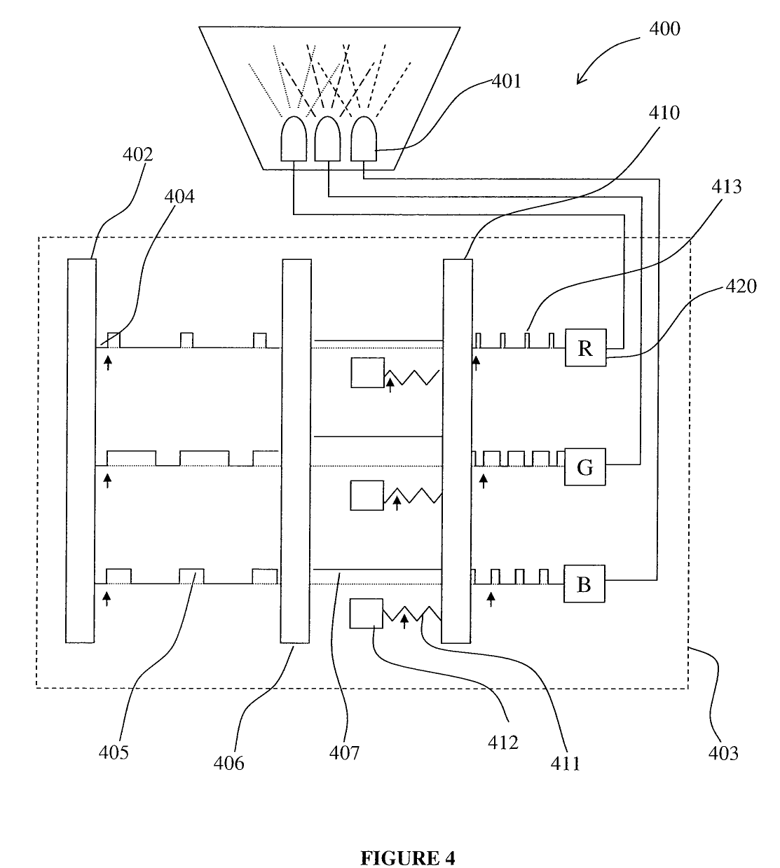

With reference now to FIG. 4, a light source driven by a PWM signal, generally referred to using the numeral 400, and in accordance with one embodiment of the present invention, will now be described. The light source 400 generally comprises three light-emitting elements 401, or groups or arrays thereof, and a driving system 403 therefor.

In general, the driving module 403 comprises a generating module 402 for generating at output 404 respective first PWM signals 405 having a substantially same desired resolution. In general, a first PWM signal 405 is generated for each light-emitting element 401, or group or array of a given type or colour of light-emitting elements, and communicated via a respective channel. Each PWM signal 405 is then converted by a converting module 406 to generate a respective analog signal, as in signal 407, indicative of a duty-cycle thereof. The respective analog signals 407 are then provided as input to a comparing module 410, such as one or more high speed comparators or the like, adapted to compare the analog signals 407 to respective reference waveforms, as in saw tooth or triangle signal 411, having a desired frequency (illustratively provided by signal generators 412). By comparing the analog signals 407 with the reference waveforms 411, respective second PWM signals 413 are generated having the desired frequency and resolution. These second PWM signals 413 can then be used in driving the light-emitting elements 401 via respective drivers 420.

The generating module 402 may again comprise a microprocessor or the like, adapted to generate the first PWM signals 405 at the desired resolution but limited to generating these signals at a frequency lower than a desired frequency. For example, in one embodiment, the generating module 402 comprises a 60 MHz processor configured to generate three 14 bits PWM signals at about 3.66 kHz.

The converting module 406 may generally comprise one or more of various types of filters and/or DACs suitable in providing analog signals 407 of suitable characteristics for the application at hand. For example, a passive low pass filter comprised of a single RC circuit may be used in some applications, whereas active and/or higher order filters may used in other applications where a higher quality output is desired or required. In general, converting module will be selected to minimise output ripple but maximise speed. In the above example wherein first PWM signals 405 are generated at 3.66 kHz, a passive low pass filter may be provided with a cut-off frequency of about 1 kHz to provide adequate results. In general, the converting module should be selected to provide an effective conversion (e.g., sufficient filtering) while allowing for rapid changes in the duty-cycles of the first PWM signals 405.

The comparing module 410 generally comprises a high speed comparator that continually compares the analog signals 407 to one or more saw-tooth or triangle waveforms 411 provided on the negative input of the comparator 410 from the waveform generator(s) 412 or the like. The frequency of the saw-tooth or triangle waveform(s) 411 can be set at the desired frequency, for example 30 kHz, such that the PWM signals 413 generated at the output 414 of the comparator 410 will generally consist of reproduced PWM signal having the desired resolution but the higher frequency (e.g., the original resolution of about 14 bits but a frequency of about 30 kHz instead of 3.66 kHz).

In this embodiment, the reference waveforms 411 are further phase shifted such that the output PWM signals 413 may also be phase-shifted. As discussed above, the PWM registers of common processors are generally all based on a common clock. As such, at the start of a new PWM cycle, all of the outputs are asserted at the same time causing a large current draw from the power supply. In one example, the generating module 402 could comprise such a common processor. To alleviate the load on the power supply, each reference waveform 411 may be phase shifted relative to one another such that the original synchronised PWM signals 405 may also be phase shifted by the comparator 410 to be spread over a period of time, thereby reducing a sudden load on the power supply. For example, as schematically illustrated in FIG. 4, each channel can be phase shifted by ⅓ of a PWM period such that the power supply will only generally see about ⅓ the current rise at a given time.

In one embodiment of the present invention, a single reference signal is generated for input into each comparing module associated with each group or array of light-emitting elements. In another embodiment, multiple reference signals are generated, wherein a particular reference signal is generated for use with a particular comparing module associated with a particular group or array of light-emitting elements. In this embodiment, the frequency of each of the reference signals may be different or the same. For example, if different frequencies are used for the reference signals, the resulting PWM control signal for each group or array of light emitting elements will have different frequencies. This configuration may also provide a means for reducing the draw on the power supply associated with the light source.

In one version of this embodiment, data could also be embedded in the second PWM signals 413 by frequency modulating the reference waveforms 411. If the light source 400 is driven as such, it could act as a data source or data transmitter. The reference waveforms 411 could also be modulated in other ways to transmit data, as one who is skilled in the art will readily understand.

While the analog signals 407 are illustrated herein as straight lines generally indicative of a substantially constant first PWM signal duty-cycles, the person of skill in the art will understand that variations in the first PWM signal duty-cycles will generally be reflected in the analog signals 407 such that these variations may be substantially transferred to the duty-cycles of the second PWM signals 413.

It is apparent that the foregoing embodiments of the invention are examples and can be varied in many ways. Such present or future variations are not to be regarded as a departure from the spirit and scope of the invention, and all such modifications as would be obvious to one skilled in the art are intended to be included within the scope of the following claims.

We claim:

1. An apparatus for generating a PWM signal having a desired resolution and frequency, the apparatus comprising:
a generating module for generating a first PWM signal having the desired resolution; and
a comparing module adapted to compare said first PWM signal to a reference signal indicative of the desired frequency and thereby generate a second PWM signal substantially having the desired resolution and frequency.

2. The apparatus as claimed in claim 1, further comprising a converting module for converting said first PWM signal into an intermediate signal indicative of the duty cycle of said first PWM signal, said comparing module adapted to compare said intermediate signal to said reference signal and thereby generate said second PWM signal.

3. The apparatus as claimed in claim 2, wherein said intermediate signal comprises an analog signal, said comparing module adapted to compare said analog signal to said reference signal.

4. The apparatus as claimed in claim 1, wherein said generating module comprises one or more of a microcontroller, a processor, a digital processor, a field programmable gate array, a counter, a timer and an operational amplifier.

5. The apparatus as claimed in claim 2, wherein said converting module comprises one or more of a digital to analog converter, a band pass filter, a notch filter and a low pass filter.

6. The apparatus as claimed in claim 5, wherein said converting module comprises a low pass filter, said low pass filter comprising one or more of a passive first order filter, an active first order filter, a passive higher order filter and an active higher order filter.

7. The apparatus as claimed in claim 1, wherein said comparing module comprises one or more of a comparator, an operational amplifier, a Schmitt trigger and a phase-lock loop.

8. The apparatus as claimed in claim 7, wherein said comparing module comprises a high speed comparator.

9. The apparatus as claimed in claim 3, wherein said reference signal is selected from the group comprising a triangle signal and a saw-tooth signal.

10. The apparatus as claimed in claim 3, for generating two or more simultaneous PWM signals having the desired resolution and frequency, said generating module for generating two or more simultaneous first PWM signals, said converting module for converting each of said simultaneous first PWM signals into respective analog signals, and said comparing module adapted to compare said respective analog signals to one or more reference signals and thereby generate respective simultaneous second PWM signals having the desired resolution and frequency.

11. The apparatus as claimed in claim 10, said comparing module adapted to compare said respective analog signals to respective reference signals configured to impart one or more respective signal characteristics to each of said respective simultaneous second PWM signals.

12. The apparatus as claimed in claim 11, wherein said one or more respective signal characteristics comprise one or more of a frequency, a phase and a modulation.

13. The apparatus as claimed in claim 1 for use in generating a driving signal for driving one or more light-emitting elements of a light source.

14. A method of generating a PWM signal having a desired frequency and resolution, the method comprising the steps of:
generating a first PWM signal having the desired resolution; and
comparing said first PWM signal to a reference signal indicative of the desired frequency to generate a second PWM signal substantially having the desired frequency and resolution.

15. The method as claimed in claim 14 further comprising the step of converting said first PWM signal into an analog signal indicative of the duty cycle of said first PWM signal, said comparing step comprising comparing said analog signal to said reference signal to generate said second PWM signal.

16. The method as claimed in claim 15, for generating two or more simultaneous PWM signals, said generating step comprising generating two or more simultaneous first PWM signals, said converting step comprising converting each of said simultaneous first PWM signals into respective analog signals, and said comparing step comprising comparing each of said respective analog signals with one or more reference signals to generate respective simultaneous second PWM signals having the desired resolution and frequency.

17. A light source comprising:
one or more light-emitting elements; and
a driving system for driving each one of said one or more light-emitting elements at a given frequency and at a respective relative intensity, said driving system comprising:
a generating module for generating, for each of said one or more light-emitting elements, a first PWM signal having a duty-cycle indicative of said respective relative intensity; and
a comparing module adapted to compare each said first PWM signal to a reference signal indicative of said given frequency and thereby generate a respective second PWM signal at said given frequency conducive to driving a respective one of said one or more light-emitting elements at said respective relative intensity.

18. The light source as claimed in claim 17, said driving system further comprising a converting module for converting each said first PMW signal into an analog signal indicative of said duty-cycle thereof, said comparing module adapted to compare each said analog signal to said reference signal to generate said respective second PWM signal.

19. The light source as claimed in claim 18 comprising two or more light-emitting elements, said comparing module adapted to compare each said analog signal to a respective reference signal configured to impart one or more respective signal characteristics to said respective second PWM signal conducive to driving said respective one of said one or more light-emitting elements in accordance therewith.

20. The light source as claimed in claim 19, wherein said one or more respective signal characteristics comprise one or more of a frequency, a phase and a modulation.

21. The light source as claimed in claim 20, said one or more respective signal characteristics comprising a respective phase such that a load applied to a power supply of the light source is distributed over a period of said respective second PWM signals.

22. The light source as claimed in claim 21, wherein said one or more respective signal characteristics further comprise a respective modulation, which provides for a communication of information using said two or more light-emitting elements, and wherein said respective phase provides for a substantially continuous signal to be communicated via said two or more light-emitting elements.

23. The light source as claimed in claim 17, said generating module for generating each said first PWM signal with a desired resolution providing a desired level of control on each said respective relative intensity.

24. The light source as claimed in claim 23, wherein said desired level of control is determined as a function of a desired dimming control over each said respective relative intensity.

25. The light source as claimed in claim 23 comprising two or more light-emitting elements having respective spectral outputs, wherein said desired level of control is determined as a function of a desired relative intensity control between said two or more light-emitting elements conducive to providing a controlled combined spectral output.

26. The light source as claimed in claim 25, wherein said combined spectral output comprises one or more of: a selected white light, a selected coloured light, a selected chromaticity, a selected colour rendering index, a selected colour quality scale, a selected output efficiency, a selected luminance and a selected colour temperature.

27. The light source as claimed in claim 25, wherein said desired level of control is further determined as a function of a desired dimming control.

28. The light source as claimed in claim 17, said comparing module comprising a phase-lock loop, wherein said reference signal is provided as a function of an output of said phase-lock loop.
